(19) United States
(12) Patent Application Publication
(10) Pub. No.: US 2006/0237228 A1
(43) Pub. Date: Oct. 26, 2006

(54) Printed circuit board having reduced parasitic capacitance pad

(75) Inventors: Yu-Hsu Lin, San Jose, CA (US); Shang-Tsang Yeh, Tu-Cheng (TW); Chuan-Bing Li, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/403,667

(22) Filed: Apr. 13, 2006

(30) Foreign Application Priority Data
Apr. 23, 2005 (CN) 200510034427.4

(51) Int. Cl. H05K 1/11

(52) U.S. Cl. 174/262

(57) ABSTRACT

A printed circuit board (PCB) includes a signal layer, a transmission line on the signal layer, a drill hole penetrating the signal layer, and a pad on the signal layer encircling the drill hole, wherein the pad includes an annular region and at least a port extending out from the annular region to connect with the transmission line.

### BACKGROUND OF THE INVENTION

1. Field of the Invention

The invention relates to a Printed Circuit Board (PCB), more particularly to a PCB having reduced parasitic capacitance pads.

2. General Background

Signal integrity is an important factor to be taken into account when a printed circuit board (PCB) is designed. A well-designed PCB has an elevated on-off switching speed of integrated circuits, a high density, and a compact layout of components. Parameters of the components and of the PCB substrate, a layout of the components on the PCB, and a layout of high-speed signal transmission lines all have an impact on signal integrity. In turn, proper signal integrity helps the PCB and an associated computer system to achieve stable performance. Parasitic capacitance has a negative impact on signal integrity, and is an important consideration as well in the design of the PCB.

Due to the higher density of signals on the PCB more signal layers are required, and it is inevitable vias should be used to interconnect the signal layers. A via includes a drill hole which allows forming an electrical connection between the signal layers and a pad encircling the drill hole which connects the drill hole to the transmission lines on the signal layers.

Referring to FIG. 1, a conventional four-layer PCB 40 includes a first layer 41 and a second layer 42 both penetrated by a drill hole 43. The first layer 41 is a signal layer with an annular pad 44 thereon encircling the drill hole 43, the annular pad 44 is used to form an electrical connection between the drill hole 43 and a transmission line 10 on the first layer 41. The second layer 42 is a power layer or a ground layer with an anti-pad 45 thereon, encircling the drill hole 43, the anti-pad 45 is an insulating region which is used to insulate the drill hole 43 from the second layer 42.

The pads 44, 45 on the first and the second layers 41, 42 have a coupling effect and produce a parasitic capacitance. The parasitic capacitance has a negative impact on rise time of a signal transmitted through the drill hole 43. The parasitic capacitance not only increases the rise time of the signal but distorts the signal as well. A first formula used to calculate parasitic capacitance of a via is as follows:
C=1.41*ξ*D1*T/(D1−D2)

Where C is the parasitic capacitance of a via, ξ is the dielectric constant of the PCB 40, D1 is the diameter of the annular pad 44, T is the thickness of the PCB 40, D2 is the diameter of the anti-pad 45. Using standard dimensions of a typical four-layer PCB, we have T equals 50 mils (1 mil=0.0254 mm), D1 equals 20 mils, D2 equals 32 mils, and ξ equals 4.4. Using the first formula, we find that the parasitic capacitance C of the via is 0.517 pf. A rise time for a signal passing along the transmission line and through via taking into account the parasitic capacitance of the via, is calculated according to a second formula:
t=2.2*C*(Z₀/2)
Where t is the rise time of the signal through the via with a parasitic capacitance C, and Z₀ is the characteristic impedance of the transmission line 10. If C is 0.517 pf as previously stated, then the rise time t of the signal is 31.28 ps.

In light of the second formula we must decrease the parasitic capacitance (C) to reduce the rise time (t), in light of the first formula we know that the parasitic capacitance (C) of a via is determined by the diameter of the annular pad (D1) and the diameter of the anti-pad (D2) because the dielectric constant of an associated PCB (ξ) and the thickness of the associated PCB (T) are constant, so in order to decrease the parasitic capacitance (C) we need to adjust the diameter of the annular pad (D1) and/or the diameter of the anti-pad (D2).

A conventional method for reducing parasitic capacitance (C) of a via is to drill a smaller hole and thus using a smaller pad. However, this remedy is limited by the technology of drilling and plating, because it takes a long time to drill such a small hole and it is very difficult to copperplate an inner wall of the hole. And merely using a pad of reduced diameter is not workable due to the inherent complications of accurately placing the end of a transmission line so near a via and still be properly connected to the pad.

What is needed is a PCB with a pad so designed as to reduce the parasitic capacitance of a via to enhance the signal integrity.

### SUMMARY

An exemplary printed circuit board (PCB) includes a signal layer, a transmission line on the signal layer, a drill hole penetrating the signal layer, and a pad on the signal layer encircling the drill hole, wherein the pad includes an annular region and at least a port extending out from the annular region to connect with the transmission line.

Other advantages and novel features will become more apparent from the following detailed description when taken in conjunction with the accompanying drawing, in which:

### BRIEF DESCRIPTION OF THE DRAWINGS

FIG. 1 is a section plan view of a conventional four-layer PCB;

FIG. 2 is a schematic plan view of a four-layer PCB with a via in accordance with a preferred embodiment of the present invention.

### DETAILED DESCRIPTION OF THE EMBODIMENT

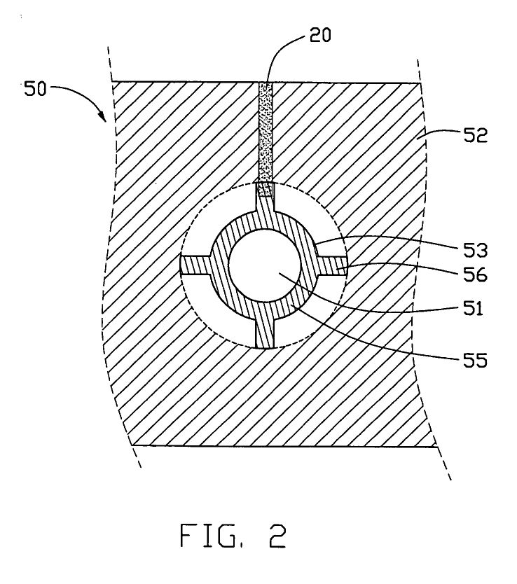

FIG. 2 shows a schematic plan view of a four-layer PCB as an example of a circuitry assembly in accordance with a preferred embodiment of the present invention. The four-layer PCB 50 includes a plurality of layers 52 and a via (not labeled), the via comprising a drill hole 51 penetrating the layers 52, a pad 53, and an anti-pad (not shown). The layers 52 at least include two signal layers, a power layer, and a ground layer.

In this preferred embodiment as shown in FIG. 2, the pad 53 is on the layer 52 and encircling the drill hole 51. The pad 53 is used to form an electrical connection between the drill hole 51 and transmission lines (only one transmission line 20 is shown) on the signal layer 52.

The pad 53 includes an annular region 55 and four extending ports 56 which extend out from the annular region 55. The extending ports 56 are distributed symmetrically and present a cross shape, the extending ports 56 are used to conveniently connect the pad 53 to the transmission line 20.

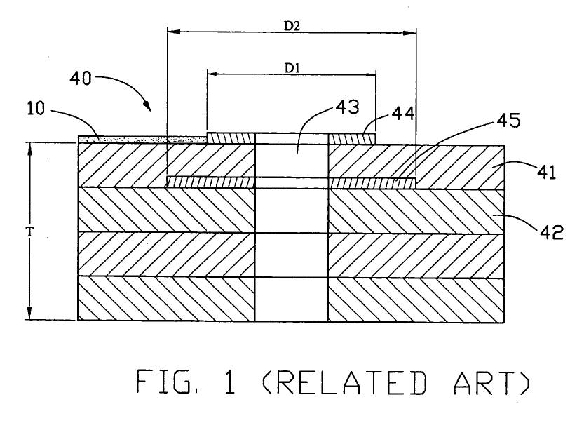

The broken line of FIG. 2 illustrates a conventional pad of FIG. 1, a general standard in industry is that the diameter of the conventional pad is equal to the diameter of the drill hole plus a minimum of 1.0 mm with 1.2 mm being average so the pad can sufficiently connect with the transmission line. In this preferred embodiment, we maintain the diameter of the pad 53 through the use of the extending ports 56, but reduce the overall area of the pad 53 by eliminating the portions of the pad 53 between the ports 56 and using the annular region 55, which can be less than 1.0 mm, to make a good connection with the drill hole. Another way to calculate parasitic capacitance of the via is using the area of the pads. According to the characteristics of a flat capacitor, the greater the area of the flat portions, the larger the capacitance of the capacitor will be, so in reducing the area of the pad 53, the parasitic capacitance of the via is reduced as well.

A conventional PCB's pad is annular, and the approximate value of the parasitic capacitance can be calculated by the first formula. The pad 53 of the preferred embodiment of the present invention has an irregular figure and the approximate value of the parasitic capacitance is not so easily calculated by the first formula. The parasitic capacitance of the drill hole 51 and the pad 53 can be calculated by inputting the planar figure of the PCB 50 into a simulation software, the parameters such as the dielectric constant of the PCB 50 and the thickness of the PCB 50 set as the foregoing, and the parasitic capacitance of the via is then calculated by use of the simulation software and found to be 0.0288 pf. According to the second formula, with the parasitic capacitance (C) equal to 0.0288 pf, and the characteristic impedance (Z₀) of the transmission line 20 equal to the transmission line 10, then the rise time (t) of the signal passing through the via of FIG. 2 is about 1.74 ps compared with 31.28 ps calculated for the signal passing through the via of FIG. 1. Therefore, with the reduction in rise time an enhancement of the signal integrity is realized.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment.

We claim:

1. A printed circuit board (PCB) having a pad to reduce parasitic capacitance of a via, the PCB comprising:
a signal layer;
a transmission line on the signal layer;
a via, the via comprising a drill hole penetrating the signal layer; and
a pad on the signal layer encircling the drill hole, wherein the pad includes an annular region and at least a port region extending out from the annular region to connect with the transmission line.

2. The PCB as claimed in claim 1, wherein said at least a port region comprises two or more port regions extending out from the annular region and the pad has an overall spoked configuration to connect with a plurality of transmission lines.

3. The PCB as claimed in claim 1, wherein a radius of the pad from a center of the pad to an outermost edge of the port region is selectable according to an industry standard for determining a desired radius of the pad.

4. A method for enhancing signal integrity for a printed circuit board (PCB), comprising the steps of:
providing a PCB which includes a signal layer;
providing a transmission line on the signal layer;
providing a drill hole to penetrate the signal layer; and
providing a pad encircling the drill hole on the signal layer, wherein the pad has a reduced area and comprises an annular region, the annular region comprises at least a port region extending out to connect with the transmission line.

5. The method as claimed in claim 4, wherein said port region comprises four port regions extending out from the annular region and present a cross shape to connect with a plurality of transmission lines.

6. The method as claimed in claim 4, wherein a radius of the pad from a center of the pad to an outermost edge of the port region being determined according to an industry standard for determining a desired radius of the pad.

7. A circuitry assembly comprising:
a signal layer of said circuitry assembly having at least one electrically conductive transmission line extending therein for signal transmission along said signal layer;
a powered layer of said circuitry assembly parallel neighboring said signal layer bearing with a predetermined voltage of power; and
a via electrically communicable with said signal layer, and extending out of said signal layer and through said powered layer, said via comprising an electrically conductive drill hole extending throughout said via and an electrically conductive pad extending along said signal layer, said drill hole occupying a first area in said signal layer and said pad occupying a second area in said signal layer surrounding said first area, said pad comprising an annular region encircling said first area of said drill hole, and at least one port region integrally formed with said annular region and extending out of said annular region to be physically reachable to a preset boundary of said second area of said pad along said signal layer so as to allow said at least one transmission line electrically connectable therewith rather than said annular region.

8. The circuitry assembly as claimed in claim 7, wherein said at least one port region comprises four extending ports symmetrically arranged around said annular region.
